(19) United States
(12) Patent Application Publication
(10) Pub. No.: US 2026/0088388 A1
(43) Pub. Date: Mar. 26, 2026

(54) METHOD FOR OPERATING A BATTERY SYSTEM

(71) Applicant: Volkswagen Aktiengesellschaft, Wolfsburg (DE)

(72) Inventors: Bastian SCHAAR, Braunschweig (DE); Carsten HENKENIUS, Marsberg/Udorf (DE); Sven MAUE, Salzgitter (DE); Karsten ROWOLD, Cremlingen (DE); Benjamin BEDUERFTIG, Ulm (DE)

(73) Assignee: Volkswagen Aktiengesellschaft, Wolfsburg (DE)

(21) Appl. No.: 19/404,620

(22) Filed: Dec. 1, 2025

Related U.S. Application Data
(63) Continuation of application No. PCT/EP2024/063345, filed on May 15, 2024.

(30) Foreign Application Priority Data
May 30, 2023 (DE) 10 2023 205 004.8

(51) Int. Cl. H01M 10/637; G01R 31/3835; H01M 10/42; H01M 10/615; H01M 10/625; H01M 10/633

(52) U.S. Cl. CPC H01M 10/637; G01R 31/3835; H01M 10/425; H01M 10/615; H01M 10/625; H01M 10/633; H01M 2220/20

(57) ABSTRACT

A method for operating a battery system having at least one electrochemical battery cell in which at least one electrochemical process that contributes to a cell internal electrical resistance of the battery cell occurs during operation. A time constant is associated with the electrochemical process. A current pulse is fed into the battery cell, and a pulse frequency of the current pulse is set on the basis of the time constant such that the electrochemical process of the battery cell is resonantly excited by the current pulse.

This nonprovisional application is a continuation of International Application No. PCT/EP2024/063345, which was filed on May 15, 2024, and which claims priority to German Patent Application No. 10 2023 205 004.8, which was filed in Germany on May 30, 2023, and which are both herein incorporated by reference.

### BACKGROUND OF THE INVENTION

### Field of the Invention

The present invention relates to a method for operating a battery system having at least one electrochemical battery cell in which at least one electrochemical process that contributes to a cell internal electrical resistance of the battery cell occurs during operation. The invention additionally relates to a battery system and to software for carrying out the method.

### Description of the Background Art

Electrically driven or drivable, or electric-motor-driven or -drivable, motor vehicles such as, e.g., electric or hybrid vehicles, generally include an electric motor with which one or both vehicle axles can be driven. The electric motor usually is connected to a vehicle-internal (high-voltage) battery system as the electrical energy storage device for the purpose of supplying electrical energy.

An electrochemical battery, in particular, should be understood here and hereinbelow as, in particular, a so-called secondary battery of the motor vehicle. In such a (secondary) vehicle battery, chemical energy that has been consumed can be restored by means of an electrical (re)charging process.

Such battery systems or vehicle batteries are implemented, for example, as electrochemical accumulators, in particular as lithium-ion accumulators. In order to create or provide a sufficiently high operating voltage, such vehicle batteries typically have at least one battery module (battery cell module), in which multiple individual electrochemical battery cells are wired in modular fashion. Alternatively, a so-called Cell2Pack design is possible, in which the battery cells are interconnected directly, in particular in parallel, to form the vehicle battery, and are not first combined into modules.

Lithium-ion-based battery cells generally have an efficiency of approximately 95%, wherein the losses that occur are converted into thermal energy. The power of such lithium-ion battery cells typically decreases (as a function of the cell chemistry) below −5° C. (degrees Celsius). Power that can be absorbed in the charging direction generally is still more strongly temperature-dependent, wherein the power that can be absorbed is limited at temperatures as high as +20° C. and below. This has a particular impact on fast charging processes in which the vehicle battery is to be charged in the shortest possible time.

The available power of the vehicle battery is thus largely dependent on its state of charge (SOC) and its battery temperature. In the case of a fully charged vehicle battery, it is necessary for the vehicle battery to have a certain operating or battery temperature in order to improve the range and the available power of the electrically driven or drivable motor vehicle.

Consequently, high-voltage batteries require thermal conditioning (heating/cooling) for constantly optimal operation and best possible performance (performance capability). Especially in the cold state at temperatures significantly below room temperature, the electrochemical processes in the interior of the battery cells proceed only very slowly. This reduces driving performance and fast-charge capability in cold environments. Particularly when the motor vehicle is stationary, for example during the course of a (re)charging process, it can occur that the battery temperature is cooled down or reduced to such an extent that the vehicle battery does not permit optimal power output or power draw at the start of a driving process, which is to say when travel of the motor vehicle is resumed or started. Moreover, especially during charging, the danger exists that the battery cells are irreversibly damaged by the deposition of metallic lithium on the anode (so-called lithium plating). Consequently, the charge currents permitted by the battery management system at low temperatures generally are very severely limited, resulting in long charging times.

In order to be able to provide adequate driving and charging performance, even in a cold environment, electrically driven or drivable motor vehicles are frequently equipped with heating systems for the battery system.

For example, externally positioned heating elements or heating devices are provided on the battery housing of the vehicle battery or on the cell housings, although these heat only the housing of the battery or cell at first. In contrast, a temperature of the internal active material of the battery cells, only begins to rise with a time delay after heating of the battery housing and cell housing. Furthermore, the heating is energetically ineffective because of the thermal losses in warming the cell housing, so an insufficient heating effect is produced on the whole.

Alternatively, an electric heater is used that heats a cooling water of the battery system, for example. This water is circulated in a battery temperature control circuit and is carried to the battery system in this way. The heating function by means of the water heater is relatively sluggish, since water must first be heated and transported by the temperature control circuit to the battery. Here, too, the heat must first arrive at the battery cells from the cooling plates through any gap filler layers. Moreover, losses occur all along this thermal pathway, further reducing the efficiency of this heating method.

It is known from CN 106532187 A, for example, to alternately charge and discharge the battery cells with an alternating current, which is to say to alternately feed a charge current and draw a discharge current, for the purpose of heating. The ensuing current flow causes a self-heating of the cells through losses at their internal resistance (cell internal resistance).

In the case of so-called “pulsed heating,” the alternating current is fed and/or drawn in the form of high frequency current pulses, in particular. Generally, the vehicle battery is coupled to the electric motor through an intermediate circuit and a (pulse-width modulation) inverter. For the pulsed heating, it is possible to send high-frequency current pulses to the vehicle battery by means of the pulse-width modulation inverter (PWM inverter) in this case. In this process, a certain quantity of energy is drawn from the vehicle battery and temporarily stored in the magnetic field of the stator coils of the electric motor. Subsequently, the polarity is reversed, the magnetic field decays, and the energy is fed back into the vehicle battery or into the battery cells as a current pulse. In this way, an energy oscillation occurs between the battery cells and the electric motor, bringing about an increase in the cell temperatures on account of the cell internal resistances.

Advantageously, the heat arises directly where it is needed, at the internal resistance of the battery cells. In the drives used in electrified vehicles, however, the inductance of the stator coils generally is dimensioned relatively small. This makes it necessary for the pulsed heating method to work with relatively high pulse frequencies in order to achieve technically useful heating powers. It proves to be disadvantageous in this context that the effective internal resistance of the battery cells (real part of the cell impedance) is very small at high frequencies, which limits the achievable heating power. This can be avoided with a separate control element and a capacitive energy storage device, for example. On account of the relatively large storage device, this makes possible even low-frequency pulses, for which the effective internal resistance of the cells for the heating is larger, so that comparatively greater heating powers become possible for the same pulse current.

### SUMMARY OF THE INVENTION

It is therefore an object of the present invention to provide an especially suitable method for operation of a battery system. In particular, an object is to specify reliable and safe temperature control or heating of battery cells. The invention has the additional object of specifying a battery system and software.

The advantages and embodiments cited with respect to the method can also be applied correspondingly to the battery system and/or the software and vice versa. The conjunction “and/or” should be understood here and hereinbelow such that the features linked by means of this conjunction can be implemented both jointly and as alternatives to one another.

When method steps are described below, advantageous embodiments for the battery system are produced, in particular by the means that this system is designed to carry out one or more of these method steps.

The method according to the invention is intended for operating a battery system, as well as being suitable and configured for this purpose. The method is generally suitable for battery systems that are (cold) started at low ambient temperatures and should have increased power or performance in this case. The battery system preferably is implemented as a vehicle battery of a battery electric vehicle, for example of a hybrid or fully electric (motor) vehicle. Alternatively, the battery system can be designed for other battery-electric products or as a stationary energy storage device, for example.

The battery system in this case can have at least one electrochemical battery cell. Preferably, the battery system can be designed on a lithium-ion basis, wherein the electrochemical battery cell accordingly is a lithium-ion cell, for example a thin-film cell with a liquid electrolyte. In the battery cell, at least one electrochemical process that contributes to a cell internal electrical resistance, in particular a cell impedance, of the battery cell occurs during battery or cell operation.

A time constant is associated with the at least one electrochemical process, and a current pulse is fed into and/or drawn from the battery cell. According to the invention, a pulse frequency of the current pulse is set on the basis of the time constant such that the electrochemical process of the battery cell is resonantly excited by the current pulse. In other words, the pulse frequency is tuned on the basis of the time constant such that the electrochemical process is excited in an intensified manner. In this way, an especially suitable method for operating a battery system is realized.

The described behavior for the pulsed heating function known from the prior art is utilized in that the frequency of the current or heating pulses is deliberately chosen in view of the time constants of the electrochemical processes within the battery cell. In contrast to known solutions, in the proposed method the pulse frequency, and preferably also the pulse shape and/or pulse amplitude and/or pulse phase, are tuned to concrete electrochemical processes within the battery cell during pulsed heating. As a result, a resonance with specific electrochemical processes can be used for targeted heating of individual cell components.

If the pulse frequency (f) corresponds to exactly the reciprocal of the time constant (T) of one of the electrochemical processes taking place within the battery cell (f=1/T), for example, this process is excited and brought into resonance (resonant frequency). This permits targeted introduction of heat energy into specific regions of the battery cell. If, for example, the kinetics of the storage reaction at the anode limit a fast charging process, the active centers at this electrode can be selectively heated in this way.

“Resonantly excited” or a “resonant excitation” can be understood here and hereinbelow as, in particular, an intensified (periodic) excitation of the electrochemical process when it is subject to the time-variable action of the current pulse. A stronger effect of the electrochemical process on the cell internal resistance/the cell impedance can be realized in this case than with a constant action (direct current charging/discharging). In the case of a periodic excitation of the electrochemical process, the excitation or pulse frequency (or an integer multiple hereof) lies in the vicinity of the resonant frequency of the electrochemical process, which is to say in a specific frequency range around the resonant frequency or the reciprocal of the time constant of the electrochemical process.

The method according to the invention thus generates heat directly inside the battery cell without detours or losses such as in a water circuit. The heating power (heating performance) achieved is brought about by targeted activation of individual electrochemical processes within the battery cell. In particular, a targeted introduction of heating power into performance-critical cell components (e.g., anode during fast charging) is thus made possible.

An “electrochemical process” can be understood here and hereinbelow as, in particular, an electrochemical reaction or an electrochemical process in the interior of the battery cell that brings about a (local) change of a state within the battery cell on account of an electric current, which change influences the electrical conductivity of the battery cell and consequently changes the electrical internal resistance or the impedance of the battery cell. Furthermore, movements or changes in the charge carriers (electrons, ions) in the battery cell or its components (such as current collectors) are also understood as an “electrochemical process.”

Within a battery cell, a great many different electrochemical processes take place that contribute to the cell internal resistance or the cell impedance. Mentioned here by way of example are charge transfers of lithium ions at the anode and cathode, formation of electrochemical double layers, and diffusion processes. In addition, a distinction is made in diffusion processes between diffusion in the electrolyte (i.e., within the electrolyte-filled pore structure of separator and electrodes) and diffusion in the solid (which is to say within the active material). Each of these processes makes a contribution to effective cell impedance and has an individual time constant.

If the impedance spectrum of the battery cell is plotted in the complex plane (Nyquist plot), the individual processes manifest in the form of half-circles. Equivalent circuit models are frequently employed in electrical modeling of battery cells. The individual processes can be represented by a parallel connection of a capacitance and a resistance (RC element) in this case (see, for example, Gaberscek, M: Impedance spectroscopy of battery cells: Theory vs. Experiment, Current Opinion in Electrochemistry, 2022, 32:100917), which is incorporated herein by reference. The time constant of the respective process then results as the product of the (total) capacitance and the (total) resistance (T=R*C).

A “current pulse” can be understood, in particular, to be an alternating current signal of a specific (pulse) duration and with a predetermined alternating current frequency (signal frequency). The alternating current signal in this case can have just one (pulse) signal component with one pulse frequency so that the current pulse is essentially a sinusoidal signal. The alternating current signal can, however, also have multiple signal components with different pulse frequencies, pulse amplitudes, and/or pulse shapes, wherein the current pulse is essentially the resultant superposition of the individual signal components.

The methods known from the prior art can be used for technical implementation of the current pulse, which is to say, for example, generation of the current pulse by a pulse-width modulation inverter with inductive storage in stator coils of an electric machine/an electric motor, by a separate control device with separate energy storage device, e.g., capacitive energy storage device, or by combinations hereof.

Preferably, the current pulse is fed periodically into the battery cell in order to achieve a reliable, resonant heating (up) of the battery cell. Thus, for example, a number of successive current pulses are fed so as to warm the battery cell. Expediently, the periodicity or repetition frequency of the current pulse is likewise chosen with regard to the resonant excitation of the electrochemical process.

In addition or alternatively to feeding a charge current pulse, a draw of a discharge current pulse can also be used correspondingly. In this way, the cell power is improved in general, even in the discharge direction, for instance in order to establish driving readiness in a cold environment more quickly or to provide required driving performance more quickly. In order to warm or heat the battery cell, preferably an energy oscillation between the battery cell and an energy storage device (for example, inductances of stator coils) is used, wherein current pulses have components in both the charging and discharging directions. In a preferred embodiment, asymmetric current pulses, in particular, which have a lower C-rate in the charging direction than in the discharging direction, are used.

In addition to the resonant heating of the battery cell, the initiation of aging-sensitive processes can be avoided in a corresponding manner. In the battery cell, at least one aging process with which a time constant can likewise be associated occurs during operation. Consequently, in one possible improvement, the pulse frequency of the current pulse can be set such that a specific aging process of the battery cell is excited little to not at all by the current pulse. This can be useful when the respective aging process has been identified as critical with regard to cell aging. Preferably, the pulse frequency of the current pulse is therefore chosen such that the electrochemical process is excited resonantly and the aging process is excited as little as possible. The service life of the battery cell is improved by the non-activation of aging-sensitive processes during heating. In addition, owing to the resonant heating, the cell power is not operated in an otherwise unheated temperature range that strongly promotes aging for the battery cell.

An “aging process” can be understood here and hereinbelow as, in particular, an electrochemical process in the interior of the battery cell that affects the aging of the battery cell. The aging process is, in particular, an irreversible process that permanently affects the cell properties. Such aging processes irreversibly influence the (remaining) capacity of the battery cell as well as the cell internal resistance or the cell impedance, among other parameters. Aged battery cells typically have a reduced capacity and (permanently) higher cell internal resistance than at the start (beginning-of-life). Relevant aging processes here include lithium plating, layer thickness growth, and gas formation within the battery cell.

In an especially simple embodiment of the method, a sinusoidal current pulse with only one excitation or pulse frequency is used, which is directed specifically toward the diffusion in the anode, for example.

A superposition of multiple excitation or pulse frequencies in the current pulse, hereinafter also referred to as the heating pulse, can also be used, which frequencies are tuned to the time constants of different electrochemical processes. In a suitable embodiment, one time constant is associated with each of a number of different electrochemical processes of the battery cell for this purpose, and a current pulse with a superposition of a corresponding number of pulse frequencies is generated, wherein the pulse sequences are set on the basis of the time constants such that the respective electrochemical processes of the battery cell are resonantly excited by the current pulse. This means that the heating pulse is implemented as a non-sinusoidal current pulse in which multiple excitation frequencies are contained. In this way, not just one, but multiple time constants, and consequently multiple electrochemical processes within the battery cell, can be activated/excited in a targeted manner, thus improving the heating power.

A total of three frequency components can be superposed to form an overall heating pulse. These components differ significantly in their time constants. As a result, optimized heating power is made possible through activation of multiple processes with widely separated time constants.

The first excitation frequency in this case is tuned particularly to an electron motion in the current collectors of the battery cell. The current collectors are made of a copper material (for anodes) or of an aluminum material (for cathodes), for example. The electron motion in the metallic current collector material is a very rapid process with a small (low) time constant. Accordingly, the first excitation frequency is a high-frequency excitation. At very high pulse frequencies in the range of 100 Hz (hertz) to above 5 kHz (kilohertz), only a pure electrical conduction within the battery cell (bus bars, current collector films), in particular, is excited, and possibly charge exchanges of internal double layer capacitances. High C-rates of the pulse current (pulse current rate) of 5 C to 10 C (depending on cell design), for example, would be possible for this purpose.

The second excitation frequency is tuned particularly to the motion of solvated lithium ions that are dissolved in the electrolyte. The motion in this case has an intermediate time constant, so the second excitation frequency is an intermediate excitation frequency. In an intermediate frequency range between 50 mHz (millihertz) and 10 Hz, storage and release reactions of lithium ions at the anode and cathode, in particular, are excited. For this purpose, the permissible pulse current rate is reduced to, e.g., 0.25 C to 1 C (depending on cell temperature).

The third excitation frequency is tuned particularly to the comparatively slow motion of the lithium ions stored in the electrodes (anode, cathode) by diffusion or changing lattice positions. This motion has a large (high) time constant, so that a low-frequency excitation, in particular, is caused by the third excitation frequency. For example, in a frequency range between 5 mHz and 50 mHz, diffusion processes are excited in the electrolyte. At frequencies lower than 5 mHz, diffusion processes within the active material (which is to say solid diffusion) also come into play. It is therefore necessary to reduce the pulse excitation to, for example, 0.1 C to 0.2 C as a function of the cell temperature.

Different pulse amplitudes and/or pulse phases can be associated with the different pulse frequencies. This means that the pulse components of the heating pulse differ from one another with regard to frequency, amplitude, and phase. In this context, particularly the amplitudes or current intensities of the low-frequency pulse components are chosen such that an accelerated aging of the cell is avoided.

During an excitation of a number of electrochemical processes that have a purely ohmic effect on the cell internal resistance/the cell impedance when excited, the processes are generally in phase so that the pulse phases of the pulse components preferably are equal. In the case of solvation of the ions, phase differences between 0° and 45° can be present, wherein the phase difference for diffusion in the solid can be up to 90°, for example.

The time constants of the electrochemical processes are dependent on, e.g., (cell) temperature, state of charge (SOC), and aging of the battery cell (state of health, SOH), and therefore can change during operation. In a useful embodiment, the chosen pulse frequencies and amplitudes and/or pulse shapes of the current pulse are tracked on the basis of a cell state. A “cell state” should be understood here to mean, in particular, an operating parameter of the battery cell, for example the cell temperature, the state of charge, or the cell aging. The frequency and pulse shape therefore are advantageously tracked, for example with increasing heating. Specifically, the processes that serve to heat the cell but prevent damage to the cell should be excited even as the heating process proceeds. The tracking in this case can be accomplished on the basis of stored characteristic curves or tables, for example.

The time constant or every time constant can be precharacterized and stored. The determination of the time constants and the identification of the individual electrochemical processes in this case can be accomplished ex situ by laboratory measurements on the battery cells for different cell states with subsequent modeling, for example. The model and/or characteristic curves and/or tables derived therefrom or corresponding thereto are stored in a memory of the battery system in this case, and thus are available on demand during operation.

Also, the time constant or every time constant can be determined during operation of the battery cell. In particular, an in situ determination of the time constants is possible here through analysis of a voltage response for the impressed or fed current pulses in the battery system. For this purpose, the current pulses are impressed and an impedance spectrum is derived. The concrete processes—excited/influenced by the current pulse—are identified herefrom and then a heating or current pulse that is tuned thereto is set.

The battery system according to the invention has at least one electrochemical battery cell in which at least one electrochemical process that contributes to a cell internal electrical resistance of the battery cell occurs during operation. The battery system additionally has an feed-in device for feeding a current pulse or heating pulse into the battery cell, and a controller (which is to say a control unit) for carrying out an above-described method.

The controller in this case can be generally configured—by means of programming and/or circuitry—to carry out the above-described method according to the invention. The controller therefore is concretely configured to set a pulse parameter (for example, pulse frequency, pulse amplitude, pulse shape), in particular a pulse frequency, of the fed current pulse on the basis of a time constant for an electrochemical process in the interior of the battery cell in such a manner that the electrochemical process is resonantly excited.

The controller can be, at least in its core, composed of a microcontroller with a processor and a data memory, in which the functionality for carrying out the method according to the invention is implemented by programming in the form of operating software (firmware) so that the method is carried out automatically—possibly in interaction with a device user—when the operating software is executed in the microcontroller. It is alternatively also possible within the scope of the invention, however, for the controller to be composed of a non-programmable electronic component, such as, e.g., an application-specific integrated circuit (ASIC), or of an FPGA (field programmable gate array), in which the functionality for carrying out the method according to the invention is implemented by means of circuitry.

The feed-in device can be coupled to a device for generating the current pulse that is controlled and/or regulated by the controller. The device in this case is designed as a pulse-width modulation inverter with inductive storage in stator coils of an electric machine/an electric motor or as a separate control device with separate energy storage device, e.g., capacitive energy storage device. Alternatively, the device for generating the current pulse can also be designed as a combination of pulse-width modulation inversion and control device. As a result, reliable generation of the current pulse or heating pulse is ensured.

An additional or further aspect of the invention provides software on a medium or data carrier, i.e. a non-transitory computer-readable medium with stored instructions, for carrying out or executing the above-described method when the software runs on a computer or controller. This means that the software is stored on a data carrier, and is intended for execution of the above-described method, as well as being suitable and designed for this purpose. As a result, especially suitable software for operating an electrically driven or drivable motor vehicle is realized with which the functionality for carrying out the method according to the invention is implemented by programming. The software is therefore operating software (firmware), in particular, wherein the data carrier is a data memory of the controller, for example.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF DRAWINGS

The present invention will become more fully understood from the detailed description given hereinbelow and the accompanying drawings which are given by way of illustration only, and thus, are not limitive of the present invention, and wherein:

FIG. 1 shows a motor vehicle with a battery system, in a schematic representation,

FIG. 2 shows the battery system in a schematic representation,

FIG. 3 shows a battery cell and a feed unit of the battery system, in a schematic representation,

FIG. 4 shows a cell impedance diagram for electrochemical processes of the battery cell,

FIG. 5 shows a flowchart for a method for operating the battery system, and

FIG. 6 shows a flowchart for an alternative method for operating the battery system.

### DETAILED DESCRIPTION

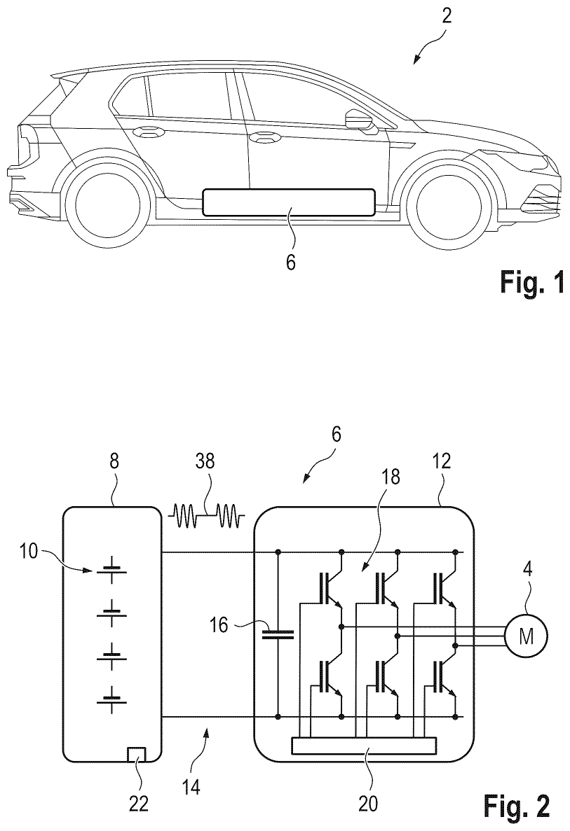

FIG. 1 shows an electrically driven or drivable motor vehicle 2, for example an electric or hybrid vehicle. The motor vehicle 2 has, as an electric traction drive, a three-phase electric motor 4 (shown in FIG. 2), which is connected to a battery system 6 for the purpose of supplying electrical energy.

The battery system 6 has an electrochemical energy storage device 8 with a number of electrochemical battery cells 10. For the purpose of generating or providing a sufficiently high operating voltage, the battery cells 10 can be wired in modular fashion to form at least one battery module. Alternatively, a so-called Cell2Pack design is possible, in which the battery cells 10 are interconnected directly, and are not first combined into modules.

Connected between the energy storage device 8 and the electric motor 4 is a pulse-width modulation inverter as feed-in device 12. In this exemplary embodiment, the battery system 6 further includes an intermediate circuit (DC link) 14 that connects the energy storage device 8 and the feed-in device 12 and that extends at least partially into the feed-in device 12. The intermediate circuit 14 is routed at least partially into the feed-in device 12, in which an intermediate circuit capacitor 16 and a bridge circuit 18 are wired.

During operation of the electric motor 4, an input current supplied to the bridge circuit 18 is converted into a three-phase output current (motor current, three-phase alternating current) for the three phases of the electric motor 4. The output currents, also referred to below as phase currents, are routed to the corresponding phase (windings) of a stator.

The bridge circuit 18 in this exemplary embodiment is designed as a B6 circuit. In this embodiment, a clocked switching between the voltage levels of the intermediate circuit 14 takes place at a high switching frequency at each of the phase windings during operation. This clocked driving is carried out as a PWM-driving by a controller 20 of the feed-in device 12 with which a control and/or regulation of the speed, the power, and the direction of rotation of the electric motor 4 is possible.

The battery system 6 additionally has a (battery) controller 22 for controlling and/or regulating operation of the energy storage device. The controllers 20, 22 in this case can be driven by a battery management controller, or integrated therein.

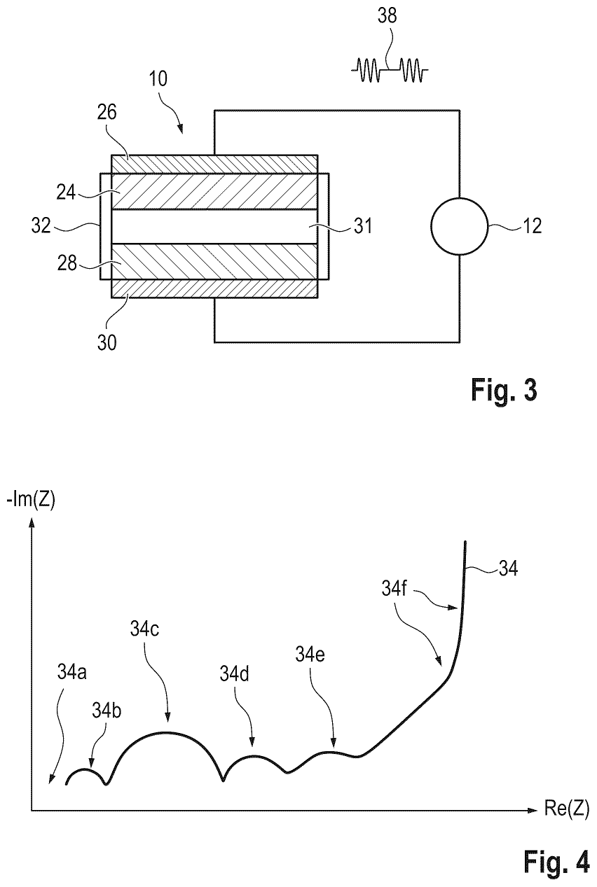

The structure of a battery cell 10 is shown in detail in FIG. 3. The electrochemical battery cell 10 is designed as a lithium-ion cell, in particular. In the exemplary embodiment shown, the battery cell 10 has a cathode 24 with a (cathode) current collector 26 and an anode 28 with an (anode) current collector 30, which are separated by a separator 31 and are coupled by a (liquid) electrolyte 32.

In the battery cell 10, at least one electrochemical process that contributes to a cell internal electrical resistance, in particular a cell impedance Z, of the battery cell 10 occurs within the current collectors 26, 30 and/or the electrode layers 24, 28 and/or the electrolyte 32 during battery or cell operation.

In a schematic and simplified cell impedance diagram, FIG. 4 shows an idealized curve of the cell impedance Z. In the cell impedance diagram, the real part of the cell impedance Z is plotted along the abscissa (x-axis), and the negative imaginary part of the cell impedance Z along the vertical ordinate axis (y-axis).

A curve 34 for the cell impedance Z or for the cell impedance spectrum is shown in the diagram. The curve 34 in this case has different sections, which are determined by different electrochemical processes. The curve 34 has essentially six regions 34a, 34b, 34c, 34d, 34e, and 34f in this case.

In the low-resistance region 34a, the cell impedance Z is governed by the electronic resistance and the resistance of the electrolyte 32. The region 34b is determined by the contact impedance between the current collectors 26, 30 and the associated electrodes 24, 28. In the region 34c, the cell impedance Z is determined particularly by the charge transfer and the double layer storage. The region 34d is characterized by diffusion processes in the pore structure of the electrodes, wherein the region 34e is determined by the diffusion in the separator 31, in particular. The region 34f corresponds to the diffusion processes in the active material of the electrodes 24, 28.

A method for operating the battery system 6 that achieves a local heating of the battery cells 10 or their (battery) cell components 24, 26, 28, 30, 31, 32 while taking into account the electrochemical processes is explained below. The method is carried out by, e.g., the battery management controller or by the controller 20 and/or the controller 22.

The heating of the battery cells 10 is accomplished here in accordance with the method by a pulsed heating in which alternating current signals are fed by the feed-in device 12 as a current or heating pulse 38 into the battery cells 10, causing a heating there on account of electrical loss processes. The current pulse 38 has components in both the charging and discharging directions in this case.

To generate the current pulse 38, a certain quantity of energy is drawn from the energy storage device 8 and temporarily stored in the magnetic field of the stator coils of the electric motor 4. Subsequently, the polarity is reversed, the magnetic field decays, and the energy is fed back into the energy storage device 8 or into the battery cells 10 as a current pulse 38.

According to the method, a time constant is associated with at least one of the electrochemical processes of the battery cell 10. In this case, a pulse frequency of the current pulse 38 is set on the basis of the time constant such that the electrochemical process of the battery cell 10 is resonantly excited by the current pulse 38, so that one or more specific electrochemical processes are used for purposeful heating of individual or multiple cell components 24, 26, 28, 30, 31, 32 by means of the resonance.

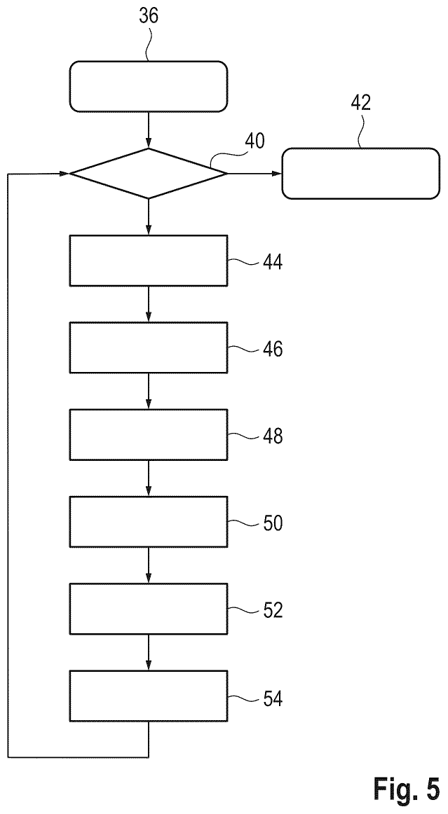

A first embodiment of the method is explained in detail below on the basis of FIG. 5.

In a method step 36, the method is started. The method in this case is started, e.g., at cold ambient temperatures of the motor vehicle 2 when the battery system 6 should have increased power or performance.

In a first method step 40, a check is first made as to whether an actual temperature of the battery cell 10 is less than or equal to a desired or stored target temperature. The controller 22 in this case is suitable and configured to monitor the temperature of the battery cell 10, for example by means of a temperature sensor or on the basis of stored temperature characteristic curves. If the actual temperature is greater than or equal to the target temperature, the method is terminated with the method step 42.

If the actual temperature is lower than the desired cell temperature, the method step 44 is carried out. A current pulse 38 is generated in the method step 44, and is fed into the battery cells 10 by the feed-in device 12 in a method step 46. Subsequently, in a method step 48, a voltage response of the battery cells 10 is sensed. For example, the controller 22 monitors the battery cells 10 by means of a voltmeter in this case.

On the basis of the sensed voltage response, the corresponding cell impedance spectrum is subsequently determined in a method step 50. The electrochemical processes excited or influenced by the current pulse 38 are identified in a method step 52. For example, the sensed voltage response is fitted to a stored model for the cell impedance, and thus the dominant processes are identified. A time constant is associated with at least one of the processes, wherein a corresponding pulse frequency is subsequently determined on the basis of the reciprocal of the time constant. In other words, an in situ determination of the time constants is accomplished here through analysis of the voltage response for the impressed or fed current pulses 38.

The determined pulse frequency is set by means of the controller 20 or the PWM-driving of the feed-in device 12. If the current cell temperature is even lower than the target temperature, the next current pulse 38 is generated with the newly set pulse frequency in the method step 44, and consequently a resonant excitation of the associated electrochemical process in the battery cell 10 is achieved.

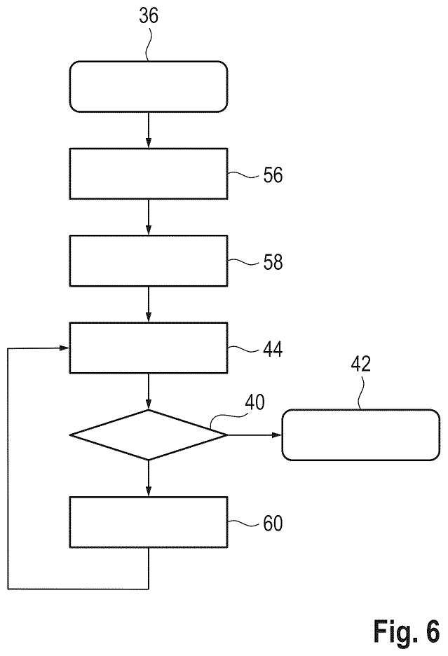

A second exemplary embodiment of the method is explained in detail below on the basis of FIG. 6. Here, the determination of the time constants and the identification of the individual electrochemical processes is accomplished ex situ by precharacterizations or laboratory measurements on the battery cells 10 for different cell states with subsequent modeling, in particular. The time constants in this case are stored in a memory of the controller 22 on the basis of characteristic curves and tables, in particular.

After the starting of the method in method step 36, the time constant for a specific electrochemical process is determined in a method step 56 on the basis of the current cell states (operating states) of the battery cell 10 (cell temperature, state of charge, state of aging, . . . ) and on the basis of the stored information. A corresponding pulse frequency is determined herefrom on the basis of the reciprocal of the time constant, and in a next method step 58, the pulse frequency is set by means of the controller 20 or the PWM-driving of the feed-in device 12. After that, the current pulse 38 is generated and fed into the battery cell(s) 10 in the method step 44.

Subsequently, a check is made in method step 40 as to whether the actual cell temperature is less than or equal to a desired or stored target temperature. If the actual temperature is greater than or equal to the target temperature, the method is terminated with the method step 42. If the actual temperature is lower than the desired cell temperature, the method step 60 is carried out.

In the method step 60, the pulse frequency is tracked. This means that, in light of the actual cell temperature (and/or other operating states) present after the current pulse 38, the time constant or pulse frequency is updated on the basis of the stored information. Subsequently the method step 44 is carried out again. It is ensured by this means that a reliable resonant excitation of the desired processes always takes place, even as the heating process progresses.

The above-described methods are also suitable for avoiding aging-sensitive processes in a corresponding manner. In particular, the pulse frequency of the current pulse 38 is set in the method steps 52, 60 in such a manner that an aging process of the battery cell 10 is excited as little as possible to not at all by the current pulse 38.

In an especially simple embodiment of the methods, a sinusoidal current pulse 38 with only one excitation or pulse frequency is used, which is directed specifically toward the diffusion in the anode (region 34f), for example. Alternatively, a superposition of multiple excitation or pulse frequencies in the current pulse 38 can also be used, which frequencies are tuned to the time constants of different electrochemical processes. For this purpose, one time constant is associated with each of a number of different electrochemical processes of the battery cell in the method steps 52, 56, and a current pulse 38 with a superposition of a corresponding number of pulse frequencies is generated.

In addition to the pulse frequencies, further pulse properties, in particular a pulse shape and/or a pulse amplitude, preferably are also set for the respective pulse frequency in the method steps 52, 56.

The claimed invention is not limited to the exemplary embodiments described above. Instead, other variants of the invention can also be derived herefrom within the scope of the disclosed claims by the person skilled in the art without departing from the subject matter of the claimed invention. Moreover, all individual features described in connection with the various exemplary embodiments can, in particular, also be combined in other ways within the scope of the disclosed claims without departing from the subject matter of the claimed invention.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for operating a battery system having at least one electrochemical battery cell in which at least one electrochemical process that contributes to a cell internal electrical resistance of the battery cell occurs during operation, the method comprising:
associating a time constant with the electrochemical process;
feeding a current pulse to the battery cell; and
setting a pulse frequency of the current pulse based on the time constant such that the electrochemical process of the battery cell is resonantly excited by the current pulse.

2. The method according to claim 1, wherein at least one aging process with which a time constant is associated occurs in the battery cell during operation, and wherein the pulse frequency of the current pulse is set such that the aging process of the battery cell is not excited by the current pulse.

3. The method according to claim 1, wherein time constants are associated with each of a number of different electrochemical processes of the battery cell, wherein a current pulse with a superposition of multiple pulse frequencies is generated, and wherein the pulse sequences are set based on the time constants such that the respective electrochemical processes of the battery cell are resonantly excited by the current pulse.

4. The method according to claim 3, wherein different pulse amplitudes and/or pulse phase positions are associated with the different pulse frequencies.

5. The method according to claim 1, wherein the pulse frequency or every pulse frequency and/or a pulse shape of the current pulse is tracked based on a cell state of the battery cell.

6. The method according to claim 1, wherein the time constant or every time constant is precharacterized and stored.

7. The method according to claim 1, wherein a voltage response of the battery cell to the current pulse is sensed, and wherein the time constant or every time constant is determined from the voltage response.

8. A battery system comprising:
at least one electrochemical battery cell in which at least one electrochemical process that contributes to a cell internal electrical resistance of the battery cell occurs during operation;
a feed-in device for feeding a current pulse into the battery cell; and
a controller to carry out the method according to claim 1.

9. The battery system according to claim 8, wherein the feed-in device has a pulse-width modulation inverter coupled to an electric motor or has a control device.

10. Software on a data carrier for carrying out the method according to claim 1 when the software runs on a computer.
